(19) United States
(12) Patent Application Publication
(10) Pub. No.: US 2026/0348046 A1
(43) Pub. Date: Nov. 5, 2026

(54) SEMICONDUCTOR PROCESSING SYSTEMS AND METHODS FOR CONTROLLING PRECURSOR GAS FLOW IN CHAMBER BODIES DURING DEPOSITION OF MATERIAL LAYERS

(71) Applicant: ASM IP Holding B.V., Almere (NL)

(72) Inventors: Caleb Miskin, Mesa, AZ (US); Tilak Thapaliya, Chandler, AZ (US); Gregory Deye, Seattle, WA (US); Mohamed Ebaid Abdrabou Hussein, Gilbert, AZ (US); Junwei Su, Chandler, AZ (US); Wentao Wang, Chandler, AZ (US); Fan Gao, Chandler, AZ (US); Aniket Chitale, Phoenix, AZ (US)

(21) Appl. No.: 19/658,825

(22) Filed: Apr. 27, 2026

Related U.S. Application Data
(60) Provisional application No. 63/797,857, filed on Apr. 30, 2025.

(51) Int. Cl. C30B 25/14; C23C 16/448; C23C 16/455; C23C 16/458; C23C 16/52; C30B 25/08; C30B 25/12; C30B 25/16; H10P 14/20

(52) U.S. Cl. CPC C30B 25/14; C23C 16/4481; C23C 16/45591; C23C 16/4584; C23C 16/52; C30B 25/08; C30B 25/12; C30B 25/16; H10P 14/3411; H10P 14/3441

(57) ABSTRACT

Semiconductor processing systems including a chamber body divided into upper and lower chambers are disclosed. The semiconductor processing system features a gas delivery module with a precursor source and a carrier gas source, supplying distinct gas flows to the upper and lower chambers through separate conduits. A controller independently manages the flow rates and precursor mass fractions of these gas flows, allowing precise control over the deposition process. Methods for depositing a material layer on a substrate employing such a semiconductor processing system are further disclosed.

### CROSS-REFERENCE TO RELATED APPLICATIONS

This application is a nonprovisional of, and claims priority to and the benefit of, U.S. Provisional Patent Application No. 63/797,857, filed Apr. 30, 2025 and entitled “SEMICONDUCTOR PROCESSING SYSTEMS AND METHODS FOR CONTROLLING PRECURSOR GAS FLOW IN CHAMBER BODIES DURING DEPOSITION OF MATERIAL LAYERS,” which is hereby incorporated by reference herein.

### FIELD

The present disclosure relates generally to the field of semiconductor processing systems and to the fabrication of semiconductor devices. More particularly, the present disclosure relates to semiconductor processing systems configured for depositing material layers onto a substrate with controlled profiles and associated methods for depositing material layers with such profiles.

### BACKGROUND

Gas-phase reactors, such as chemical vapor deposition (CVD) reactors and the like, can be used for a variety of applications, including depositing, etching materials on a substrate surface, and cleaning of a surface of the substrate. For example, gas-phase reactors can be used to deposit epitaxial layers on a substrate to form devices, such as semiconductor devices, flat panel display devices, photovoltaic devices, microelectromechanical systems (MEMS), and the like.

A typical gas-phase epitaxial reactor system includes a reaction chamber, a gas delivery module to deliver gases (e.g., precursors, reactants, etchants, purge gases, carrier gases, and the like) to the reaction chamber, a substrate support, such as a susceptor, to retain and heat a substrate disposed within the reaction chamber, and an exhaust module fluidly coupled to the reaction chamber. Further, epitaxial reactor systems can include one or more heaters (e.g., lamps) and/or temperature measurement devices (e.g., a thermocouple).

During deposition, such as an epitaxial deposition, and particularly during deposition of doped or multi-component layers, it is often desirable to control layer properties, such as a thickness profile and/or a composition profile of a deposited material layer from the center to a far edge of the material layer upon the substrate. In particular, the profile of the material layer at the outer edge of the substrate can be challenging to control, such as, for example, at the outer about 5% to about 15% of the radius of the substrate. Accordingly, improved semiconductor processing systems and methods are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to improved apparatus, systems, and methods suitable for depositing material layers on a surface of a substrate and/or other processes. While the ways in which various embodiments of the present disclosure address drawbacks of prior systems and methods are discussed in more detail below, in general, various embodiments of the disclosure provide semiconductor processing systems and methods that can be used, for example, to deposit epitaxial layers in a more controlled manner. For example, exemplary apparatus, systems, and methods can be used to reduce and/or control roll-up and/or roll-down at the far edge of a substrate while processing the substrate. Examples of the disclosure can provide improved uniformity of film thickness, composition, dopant concentration, and/or the like.

Various embodiments of the present disclosure relate to semiconductor processing systems. As set forth in more detail below, embodiments described herein can be used during the manufacture of semiconductor devices. Such embodiments can provide precise gas flow control, improved deposition uniformity, while potentially accommodating dopant incorporation with a defined non-uniformity range. By way of example, the semiconductor processing systems described herein may be employed in chemical vapor deposition processes, epitaxial deposition, and various other semiconductor fabrication techniques.

In accordance with examples of the present disclosure, one embodiment includes a semiconductor processing system comprising a chamber body, a fixed divider having an aperture that fluidly couples an upper chamber to a lower chamber, and a rotatable substrate support arranged within the aperture. A system further includes a gas delivery module comprising a precursor source assembly configured for supplying a precursor gas, a carrier source for supplying a carrier gas, a lower precursor conduit that couples the gases from the sources to the lower chamber (and through the aperture to the upper chamber), and an upper precursor conduit configured to supply gases directly to the upper chamber. In some embodiments, a controller having non-transitory machine-readable memory is operatively connected to the gas delivery module, wherein the controller is configured to independently control a first gas flow through the lower conduit and a second gas flow through the upper conduit. In some embodiments, the lower conduit includes a tube disposed within a shaft member that extends through a lower wall of the chamber body, the shaft member coupling the substrate support to a drive module. Moreover, one or more flow controllers provided along the conduit deliver a first gas flow having a defined precursor mass fraction, while the upper conduit may incorporate an injection flange, and the precursor source assembly may include a dopant source configured to deposit a doped material layer on a substrate within a specified dopant percentage non-uniformity.

In another embodiment of the disclosure, a chemical vapor deposition system is provided for performing epitaxial deposition processes. In accordance with such embodiments, the system comprises a reaction chamber including a chamber body with an upper wall—extending between an injection end and an exhaust end—and a lower wall situated parallel and below the upper wall. A substrate support, which at least partially defines a lateral plane within the chamber, is arranged to hold a substrate during processing. The gas delivery module is coupled to the chamber body and further comprises a precursor source assembly and a carrier source. In accordance with these embodiments, a lower precursor conduit, linked to the sources by one or more lower flow controllers, is configured to inject a first gas flow into the chamber below the lateral plane, whereas an upper precursor conduit, connected via one or more upper flow controllers, is configured to inject a second gas flow into the chamber above the lateral plane. Accordingly, a controller having appropriate non-transitory memory instructions independently controls the precursor mass fractions of these gas flows. In some embodiments, the upper conduit is coupled to the chamber through the injection end, the lower conduit directs the first gas flow toward a susceptor, and a fixed divider with an aperture separates the interior of the chamber into upper and lower regions, the lower conduit being disposed within a shaft member that further includes a gas mixing plenum configured to mix the precursor and carrier gases.

In further accordance with examples of the disclosure, another embodiment relates to a method for depositing a material layer on a substrate using a semiconductor processing system. A method includes introducing a first gas flow with a predetermined precursor mass fraction into a lower chamber via a lower precursor conduit and independently introducing a second gas flow with a different precursor mass fraction into an upper chamber via an upper precursor conduit. In accordance with these embodiments, the injection of the gas flows is independently controlled, and the material layer is deposited on the substrate supported by the rotatable substrate support. In some embodiments, the method further includes employing flow controllers to introduce the first gas flow through a tube disposed within a shaft member and to deliver the second gas flow through an injection flange. Additionally, or alternatively, the method can involve flowing a dopant gas into the lower chamber while simultaneously introducing either the dopant gas or a silicon precursor gas into the upper chamber, thereby achieving selective deposition of a doped material layer.

These and other embodiments will become readily apparent to those skilled in the art from the following detailed description of certain embodiments having reference to the accompanying figures. The subject matter is not limited to any particular embodiments disclosed herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a schematic view of a semiconductor processing system including a gas delivery module and an exhaust module connected to a reactor in accordance with one or more embodiments of the disclosure.

FIG. 2 illustrates an expanded schematic view of a semiconductor processing system including expanded schematic views of sub-systems of a gas delivery module and a controller in accordance with one or more embodiments of the disclosure.

FIG. 3 illustrates a schematic view of a semiconductor processing system including a gas delivery module and an exhaust module connected to a chamber arrangement in accordance with one or more embodiments of the disclosure.

FIG. 4 illustrates a schematic view of a semiconductor processing system including a chamber arrangement having independently controllable gas flows through a lower precursor conduit and an upper precursor conduit, the lower precursor conduit including a tee fitting for mixing a precursor gas and a carrier gas prior to introduction into a chamber body in accordance with one or more embodiments of the disclosure.

FIG. 5 illustrates a schematic view of a semiconductor processing system including a chamber arrangement having independently controllable gas flows through a lower precursor conduit and an upper precursor conduit, the lower precursor conduit including a tube member disposed within a shaft member and having a precursor inlet port and a carrier inlet port in accordance with one or more embodiments of the disclosure.

FIG. 6 illustrates a process flow of a method for depositing a material layer on a substrate in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of example, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can be used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gases, nitrogen, and the like. In some cases, the term “precursor” can refer to a compound that participates in the chemical reaction that produces another compound, and particularly to a compound that constitutes a film matrix or a main skeleton of a film. In addition, the term “reactant” can be used interchangeably with the term “precursor.”

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

A number of example materials are given throughout the embodiments of the current disclosure; it should be noted that the chemical formulas given for each of the example materials should not be construed as limiting and that the non-limiting example materials given should not be limited by a given example stoichiometry.

As used herein, a “structure” can be or can include a substrate as described herein. Structures can include one or more layers overlying the substrate, such as one or more layers formed according to a method as described herein.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

Various embodiments of the present disclosure relate to semiconductor processing systems and methods for depositing material layers on a substrate with controlled material properties.

In certain vapor deposition processes, such as chemical vapor deposition (CVD), for example, precursor gases are crucial for the formation of material layers on substrates. When these precursor gases are introduced from an injection flange positioned a distance from the substrate, the precursor gases may undergo premature mixing prior to reaching the intended deposition zone. This early interaction of the precursor gases can lead to undesirable variations in the deposited layer's characteristics. For example, the premature precursor mixing can affect profile control of the deposited layer, which includes parameters such as profile thickness (e.g., uniform deposition is vital for ensuring consistent thickness across the wafer). In additional examples, early mixing of the precursor gases can result in non-uniform composition of the deposited layers (e.g., the intended stoichiometry may be altered if precursors react too soon, leading to layers with inconsistent elemental or compound composition). As a further example, early mixing of the precursor gases can result in an undesirable dopant concentration in the deposited material layer, for example, for processes involving doped layers, premature mixing can cause uneven distribution of dopants, affecting electrical properties like conductivity. These issues with premature precursor mixing can be a particular concern in deposition processes conducted at high pressures and/or with low carrier gas flows. In such examples, high pressure can increase the probability of interactions between precursor molecules before they reach the substrate, whereas low carrier flow can exacerbate these issues by reducing the transport efficiency, allowing more time and opportunity for premature reactions. Consequently, achieving precise control over material layer properties can become more challenging under these conditions, necessitating modified semiconductor processing systems and methods to control precursor delivery to substrates to achieve the desired deposition profile.

Accordingly, the various embodiments of the present disclosure provide semiconductor processing systems and methods that allow for additional control over the deposition profile of a material layer deposited on a substrate. In particular, the semiconductor processing systems and methods of the present disclosure provide control over the profile of one or more of the thickness, composition, and dopant uniformity of a deposited material layer. In addition, such semiconductor processing systems and methods can provide additional control over the deposition profile of a deposited layer at the outer periphery of the substrate where such control can be particularly challenging. The various embodiments of the disclosure can achieve such deposition profile control by the independent injection of precursor gases into an upper chamber of a chamber body and into a lower chamber of the chamber body. This approach allows for the injection of precursors, either independently or alongside other precursors, as well as along with a carrier gas. These semiconductor processing systems and associated methods facilitate the independent adjustment of specific precursors (e.g., dopant gases) without dependency on other precursor gases, such as silicon or etchant precursors. In the embodiments provided, the ratio of precursor gases to carrier gas can be precisely controlled over the substrate using flow controllers. For example, given the vacuum conditions within the chamber, precursors injected from the bottom predominantly affect the wafer edges, as diffusion toward the center is limited before the gases are directed towards the exhaust.

The various embodiments provided include exemplary semiconductor processing systems. Such semiconductor processing systems may comprise one or more of a chemical vapor deposition system, a plasma-enhanced chemical vapor deposition system, an atomic layer deposition system, a plasma-enhanced atomic layer deposition system, and the like. In certain examples, the exemplary semiconductor processing systems can comprise chemical vapor deposition systems configured for performing epitaxial deposition processes.

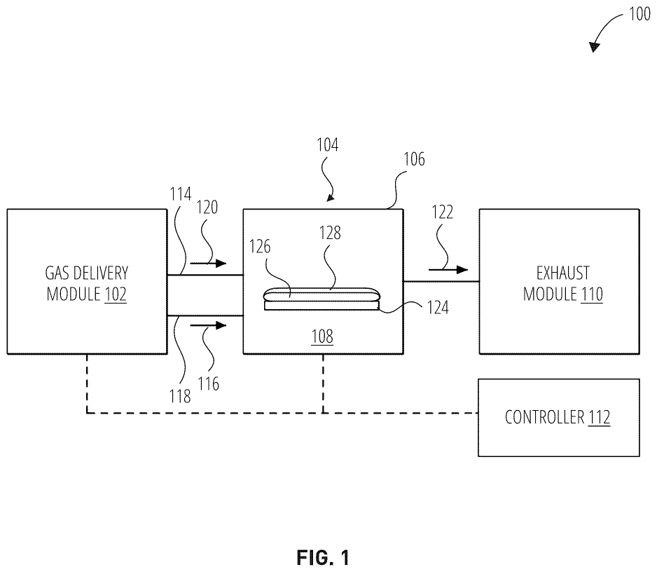

Turning now to the figures, FIG. 1 illustrates a view of a semiconductor processing system 100 including a gas delivery module 102, a chamber arrangement 104 (including a chamber body 106), an exhaust module 110, and a controller 112. The gas delivery module 102 is connected to the chamber body 106 and is configured to provide various gas flows to an interior 108 of the chamber body 106. Such gas flows can include one or more precursors (including, but not limited to, silicon-containing precursors, germanium-containing precursors, dopant gases, and the like), a carrier gas, as well as, in certain examples, a purge gas, and an etchant gas. In certain examples, and as illustrated in FIG. 1, the gas delivery module 102 can include a lower precursor conduit 118 configured to inject a first gas flow 116 into the interior of the chamber body and an upper precursor conduit 114 configured to inject a second gas flow 120 into the interior of the chamber body. In such examples, the first gas flow 116 can be injected into a lower chamber and the second gas flow can be injected into an upper chamber, where the first and second gas flows are independently controlled, as discussed in greater detail below.

As illustrated in FIG. 1, the exhaust module 110 is connected to the chamber arrangement 104, and is fluidly coupled to the gas delivery module 102 by the chamber arrangement 104. The exhaust module 110 is configured to receive a flow of decomposition products, residual precursor, and/or reaction products 122 issued by the chamber arrangement 104. The chamber arrangement 104 (and the chamber body 106) is connected to the gas delivery module 102 and the exhaust module 110, and fluidly couples the gas delivery module 102 to the exhaust module 110.

In various examples, the chamber body 106 includes a substrate support 124 configured to support a substrate 126 arranged within the interior 108 of the chamber body 106 during deposition of a material layer 128 on the substrate 126. It is contemplated that the controller 112 be operably connected to one or more of the gas delivery module 102, the chamber arrangement 104, and the exhaust module 110 to control operation of the semiconductor processing system 100. In certain examples the exhaust module 110 can include a vacuum pump and/or an abatement device, such as a scrubber apparatus.

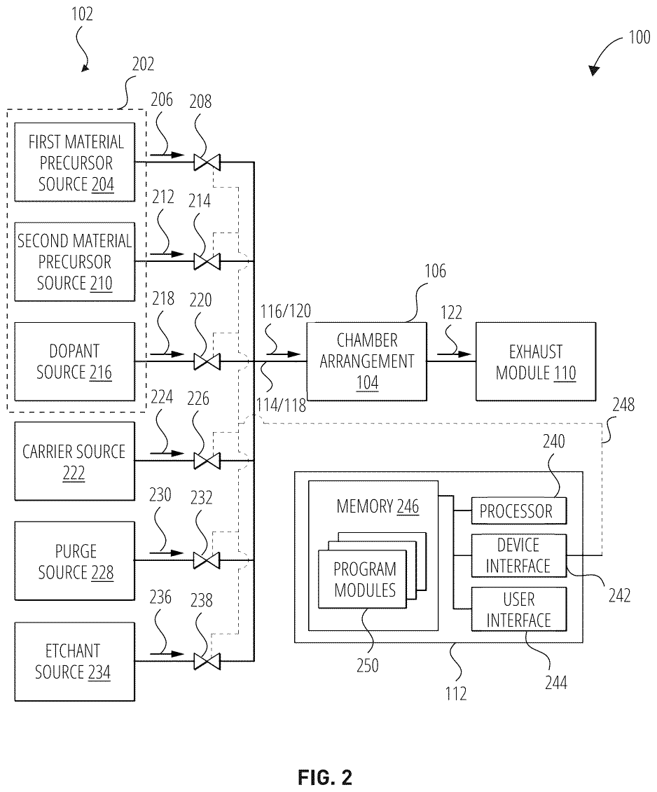

In various embodiments and with reference to FIG. 2, the semiconductor processing system 100 is further illustrated and includes an expanded illustration of an exemplary gas delivery module 102 and controller 112 in accordance with various examples. In the illustrated example, the gas delivery module 102 includes a precursor source assembly 202. The precursor source assembly 202 can include multiple sources of precursors employed in the deposition of a material layer in the chamber body 106.

As used herein, the term “precursor source” as well as an assembly of such “precursor sources” can refer to a source of a chemical precursor employed in the deposition of a material layer, where the chemical precursor itself and/or a decomposition product of the chemical precursor is intentionally incorporated into the material layer being deposited. In one example, a precursor source can include a silicon-containing precursor (as can be employed in the deposition of silicon-containing material layers, such as single crystalline silicon layers, for example). In another example, a precursor source can include a germanium-containing precursor (as can be employed in the deposition of germanium-containing material layers, such as single crystalline germanium layers, and silicon germanium (SiGe) layers, for example). In a further example, a precursor source can include a dopant gas, such as one or more of a phosphorus dopant gas, an arsenic dopant gas, an antimony dopant gas, a boron dopant gas, an aluminum dopant gas, and a gallium dopant gas, for example (as can be employed in the deposition of doped silicon, doped germanium, and doped silicon-germanium layers, for example).

In various embodiments and as illustrated in FIG. 2, the precursor source assembly 202 can include a first material precursor source 204 (e.g., a silicon-containing precursor), a second material precursor source 210 (e.g., a germanium-containing precursor), and a dopant source (e.g., a phosphorus dopant gas, such as phosphine (PH₃), phosphorus oxychloride (POCl₃), and phosphorus pentachloride (PCl₅)). In certain examples, the precursor source assembly 202 can include additional material precursor sources (e.g., oxygen, carbon, gallium, and nitrogen), and/or additional dopant sources (e.g., sources of arsenic, antimony, boron, aluminum, and gallium).

The precursor source assembly 202 can be connected to the chamber body 106 and can be configured to provide one or more gas flows to the chamber body 106. In one aspect, the first material precursor source 204 can be connected to the chamber body 106 and can be configured to provide a first material precursor flow 206 to the chamber body 106. The first material precursor source 204 can be connected to the chamber body 106 by a first material precursor valve and/or flow controller (e.g., valve 208), and is in selective communication with the chamber body 106 through the first material precursor valve and/or the flow controller. In another aspect, the second material precursor source 210 can be connected to the chamber body 106 and can be configured to provide a second material precursor flow 212 to the chamber body 106. The second material precursor source 210 can be connected to the chamber body 106 by a second material precursor valve and/or flow controller (e.g., valve 214), and is in selective communication with the chamber body 106 through the second material precursor valve and/or the flow controller. In another aspect, the dopant source 216 (or sources) can be connected to the chamber body 106 and can be configured to provide a dopant flow 218 to the chamber body 106. The dopant source 216 can be connected to the chamber body 106 by a dopant valve and/or flow controller (e.g., valve 220), and is in selective communication with the chamber body 106 through the dopant valve and/or the flow controller.

The gas delivery module 102 of FIG. 2 can further include a carrier source 222, such as, for example, one or more sources for supplying hydrogen (H₂), nitrogen (N₂), and argon (Ar), as illustrated by carrier flow 224. The carrier source 222 can be connected to the chamber body 106 by a carrier valve and/or flow controller (e.g., valve 226), and is in selective communication with the chamber body 106 through the carrier valve and/or the flow controller. The gas delivery module 102 can further include a purge source 228, such as, for example, one or more sources for supplying hydrogen (H₂), nitrogen (N₂), and argon (Ar), as illustrated by purge flow 230. The purge source 228 can be connected to the chamber body 106 by a purge valve and/or flow controller (e.g., valve 232), and is in selective communication with the chamber body 106 through the purge valve and/or the flow controller. In certain examples, the carrier source 222 and the purge source 228 can be combined into a carrier/purge gas source configured for supplying both carrier gases and purge gases to the chamber body 106.

In addition, an etchant source 234 can be connected to the chamber body 106 and can be configured to provide an etchant flow 236 to the chamber body 106. In this respect, the etchant source 234 can be connected to the chamber body 106 by an etchant valve or flow controller (e.g., valve 238), and is in selective fluid communication with the chamber body 106 through the etchant valve or flow controller. In certain examples, the etchant flow 236 may include a halide-containing gas, such as fluorine and chlorine. Examples of suitable halide-containing gases can include hydrochloric acid (HCl) and/or precursors employed to generate HCl.

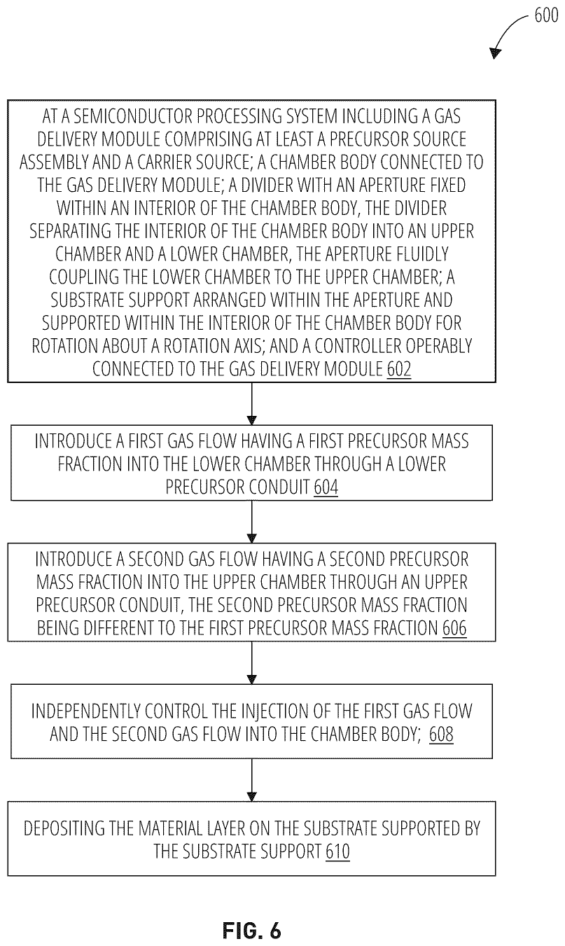

The controller 112 includes a processor 240, a device interface 242, a user interface 244, and a memory 246. The device interface 242 operably connects the controller 112 to the gas delivery module 102, for example, through a wired or wireless link 248. The processor 240 is disposed in communication with one or more of the gas delivery module 102 and the chamber arrangement 104 through the device interface 242, is operably connected to the user interface 244 to receive and/or provide user input/user output therethrough, and is disposed in communication with the memory 246. The memory 246 includes a non-transitory machine-readable medium having a plurality of program modules 250 recorded on the medium that, when read by the processor 240, cause the processor 240 to undertake certain actions. Among those actions are operations of a material layer deposition method 600 (as shown in FIG. 6), as described below. Although a specific arrangement of the controller 112 is shown in FIG. 2, it is to be understood and appreciated that other controller arrangements are possible, e.g., controllers having distributed control architectures, and remain within the scope of the present disclosure.

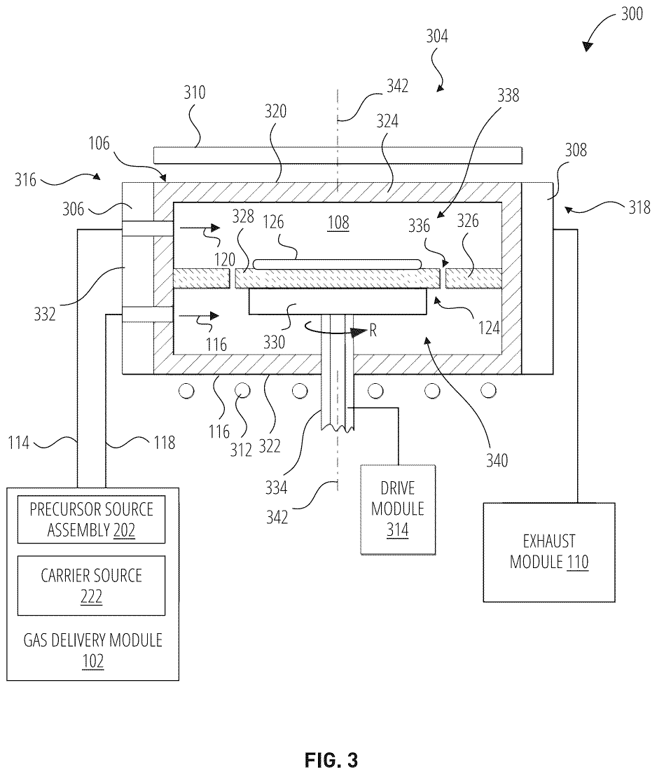

FIG. 3 illustrates a semiconductor processing system 300 including an exemplary chamber arrangement 304 in accordance with one or more embodiments of the disclosure. The chamber arrangement 304 includes an injection flange 306, the chamber body 106, and an exhaust flange 308. The chamber arrangement 304 also includes an upper lamp bank 310, a lower lamp bank 312, and a drive module 314. The injection flange 306 is connected to the chamber body 106 and couples the gas delivery module 102 to an interior 108 of the chamber body 106. The exhaust flange 308 is connected to the chamber body 106 and fluidly couples the interior 108 of the chamber body 106 to the exhaust module 110. The upper lamp bank 310 and the lower lamp bank 312 are supported above and below the chamber body 106, respectively, and are operably associated with the controller 112 (shown in FIG. 2) and are configured to radiantly communicate heat into the interior 108 of the chamber body 106.

In various embodiments, the chamber body 106 has an injection end 316 and an opposite (relative to the general direction of fluid flow through the interior 108 of the chamber body 106) exhaust end 318. The chamber body 106 can have an upper wall 320 and a lower wall 322, and can be formed from a transparent material 324 (e.g., a material transmissive to radiant energy communicated by the upper lamp bank 310 and the lower lamp bank 312), and may be a ceramic material such as quartz. The injection flange 306 is connected to the injection end 316 of the chamber body 106 and fluidly couples the gas delivery module 102 to the interior 108 of the chamber body 106. The exhaust flange 308 is connected to the exhaust end 318 of the chamber body 106 and fluidly couples the interior 108 of the chamber body 106 to the exhaust module 110. The upper wall 320 of the chamber body 106 extends longitudinally between the injection end 316 and the longitudinally opposite exhaust end 318 where the lower wall 322 is below and parallel relative to the upper wall 320. The upper wall 320 of the chamber body 106 radiantly couples the upper lamp bank 310 to the interior 108 of the chamber body 106. The lower wall 322 of the chamber body 106 is spaced apart from the upper wall 320 of the chamber body 106 by the interior 108 of the chamber body 106, extends between the injection end 316 and the exhaust end 318 of the chamber body 106, and radiantly couples the lower lamp bank 312 to the interior 108 of the chamber body 106. In certain examples, the chamber body 106 may include one or more external ribs extending along exterior surfaces of the chamber body 106. In accordance with certain examples, the chamber may have no external ribs.

In various embodiments, the chamber arrangement 304 of FIG. 3 includes a divider 326, and a substrate support 124 comprising a susceptor 328, and a susceptor support 330. The upper surface of the substrate support 124 (e.g., the upper surface of susceptor 328) can define, or at least partially define, a lateral plane 332 within the interior 108 of the chamber body 106. The divider 326 is fixed within the interior 108 of the chamber body 106 and has an aperture 336 extending therethrough. The divider 326 divides the interior 108 of the chamber body 106 into an upper chamber 338 and a lower chamber 340. The aperture 336 extending through the divider 326 fluidly couples the upper chamber 338 of the chamber body 106 to the lower chamber 340 of the chamber body 106. In certain examples, the divider 326 can be fabricated from an opaque material that may include a bulk graphite material, which may have a silicon carbide coating overlaying the bulk graphite material.

The susceptor 328 is arranged within the interior 108 of the chamber body 106 and in the aperture 336, and is supported for rotation R about a rotation axis 342. The susceptor 328 can be configured to seat thereon the substrate 126 during the deposition of a material layer 128 (shown in FIG. 1) onto the substrate 126. The susceptor 328 may also be formed from an opaque material. In accordance with certain examples, the substrate 126 may include a silicon wafer, such as a 300-millimeter wafer. In certain examples the substrate 126 may include a blanket substrate, such as a blanket wafer. In accordance with certain examples, the substrate 126 may include a patterned substrate, such as a patterned wafer.

The susceptor support 330 is arranged within the lower chamber 340 of the chamber body 106 and along the rotation axis 342, and is fixed in rotation relative to the susceptor 328. A shaft member 334 is fixed in rotation relative to the susceptor support 330. The shaft member 334 extends through the lower chamber 340 and through the lower wall 322 of the chamber body 106, and couples the susceptor 328 to the drive module 314. The drive module 314 is operably connected to the susceptor 328 through the shaft member 334 and the susceptor support 330, and is configured to rotate the susceptor 328 about the rotation axis 342. In certain examples, the drive module 314 may be operably associated with the controller 112 (shown in FIG. 2).

In various embodiments, chamber arrangement 304 includes a lower precursor conduit 118 configured to couple the gas delivery module 102, and particularly the precursor source assembly 202 and the carrier source 222 to the lower chamber 340 of the chamber body 106 and therethrough to the upper chamber 338 of the chamber body 106. In addition, the chamber arrangement 304 can include an upper precursor conduit 114 configured to couple the gas delivery module 102, and particularly the precursor source assembly 202 and the carrier source 222 to the upper chamber 338 of the chamber body 106. In certain examples, controller 112 (shown in FIG. 2) is operably connected to the gas delivery module 102 and has a non-transitory machine-readable memory with instructions recorded on the memory that cause the controller 112 to independently control a first gas flow 116 to the lower chamber 340 and a second gas flow 120 to the upper chamber 338.

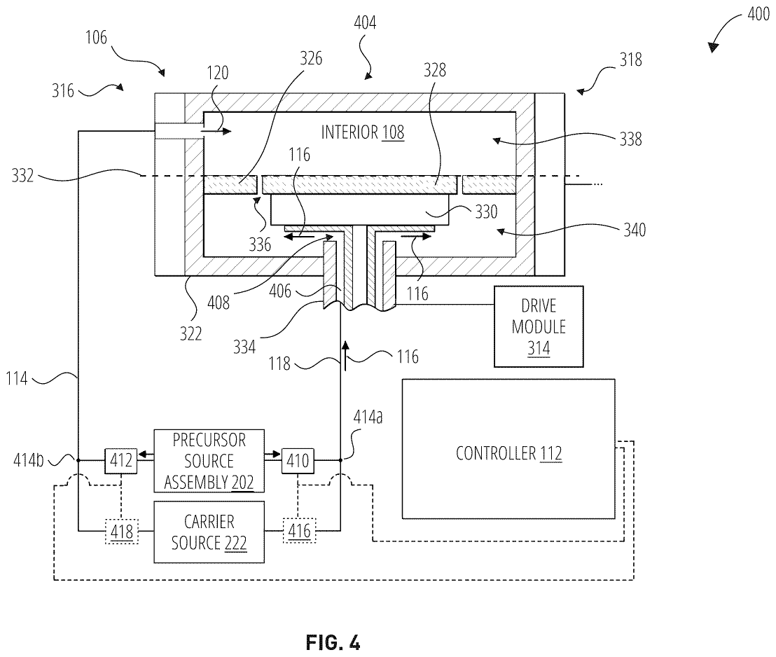

FIG. 4 illustrates a semiconductor processing system 400 including a chamber arrangement 404 in accordance with one or more embodiments of the disclosure. As illustrated in FIG. 4, the semiconductor processing system 400 includes a lower precursor conduit 118 (as illustrated previously in FIG. 1). The lower precursor conduit 118 can be configured to couple the gas delivery module 102 (of FIG. 1) and particularly the precursor source assembly 202 and the carrier source 222 to the lower chamber 340 of the chamber body 106, and therethrough to the upper chamber 338 of the chamber body 106. Additionally, an upper precursor conduit 114 is configured to couple the gas delivery module 102 (of FIG. 1) and particularly the precursor source assembly 202 and the carrier source 222 to the upper chamber 338 of the chamber body 106. In such embodiments, the semiconductor processing system 400 allows for precise control and delivery of precursor and carrier gases to different sections of the chamber body (i.e., the upper chamber 338 and the lower chamber 340), facilitating control over the deposition profile of a material layer deposited employing such a system. The gas conduits (e.g., 118, 114) ensure that the first and second gas flows (e.g., 116, 120) are directed accurately to their respective chambers, maintaining the required conditions for controlled material deposition.

In various embodiments, the lower precursor conduit 118 is fluidly coupled to the precursor source assembly 202 and the carrier source 222 by one or more lower flow controllers (as described below), the lower precursor conduit 118 being configured to inject the first gas flow 116 into the interior of the chamber body below the lateral plane 332. The lower precursor conduit 118 can be coupled to the chamber body 106 through the lower wall 322 of the chamber body 106.

In certain examples, the lower precursor conduit 118 is fluidly coupled to a single precursor source and the carrier gas source. In such examples, the single precursor can comprise a dopant source (such as dopant source 216 as illustrated in FIG. 2). In such examples, where a single precursor (i.e., a single dopant) is introduced through the lower precursor conduit 118, it can be injected independently of other precursors, along with a carrier gas. Separate injection of a sole precursor can enable the independent modulation of the precursor, such as a dopant gas, without dependence/interdependence on other precursors, such as, for example, a silicon-containing precursor, a germanium-containing precursor, an etchant, and the like. It is therefore possible to introduce a precursor through the tube member 406 within the shaft member 334 and the flow controllers enable independent regulation of the ratio between the precursor(s) and the carrier gas into the lower chamber 340, i.e., the first gas flow having a first precursor mass fraction. In addition, since the chamber body 106 can operate under vacuum conditions, the precursors injected through the lower precursor conduit can predominantly affect the substrate's edge, as it is challenging for the precursors injected from the lower precursor conduit to diffuse to the center of the substrate prior to being drawn toward the exhaust module 110, as illustrated in FIG. 1.

In various embodiments, the upper precursor conduit 114 is fluidly coupled to the precursor source assembly 202 and the carrier source 222 by one or more upper flow controllers (as described below), the upper precursor conduit 114 being configured to inject the second gas flow 120 into the interior of the chamber body above the lateral plane 332. The upper precursor conduit 114 can be coupled to the chamber body 106 through the injection end 316 of the chamber body 106.

In various embodiments, the controller 112 is operably connected to the gas delivery module 102 (as previously described in FIG. 2) and has a non-transitory machine-readable memory 246 with instructions recorded on the memory 246 that cause the controller 112 to independently control the first gas flow 116 to the lower chamber 340 and the second gas flow 120 to the upper chamber 338, as illustrated in FIG. 4. In such embodiments, the controller 112 has the ability to manage gas flows independently to the lower chamber 340 and the upper chamber 338 allowing for optimizing the processing environment within each of the upper and lower chambers. By adjusting the flow rates and compositions of the first and second gas flows (e.g., 116 and 120), the controller 112 can ensure that the conditions are tailored to the specific requirements of the semiconductor processing steps being performed.

In various embodiments, the lower precursor conduit 118 comprises a tube member 406 fluidly coupled to the interior 108 of the chamber body 106. The tube member 406 can be disposed within a shaft member 334, which extends through a lower wall 322 of the chamber body 106 and couples the substrate support 124 to a drive module 314 configured to rotate the substrate support 124.

In various embodiments, the semiconductor processing system 400 comprises one or more lower flow controllers 410 coupled to the tube member 406. The controller 112 is operably connected to the one or more lower flow controllers 410 to provide a first gas flow 116 comprising a co-flow of the precursor gas and the carrier gas to the lower chamber 340, with the first gas flow 116 having a first precursor mass fraction. The lower flow controllers 410 can regulate the first gas flow 116 to the lower chamber. By controlling the co-flow of precursor and carrier gases, these lower flow controllers can maintain the desired precursor mass fraction in the lower chamber 340.

Similarly, the upper precursor conduit 114 comprises an injection flange 306 fluidly coupled to the interior 108 of the chamber body 106 and connected to the chamber body 106. The semiconductor processing system 400 further comprises one or more upper flow controllers 412 coupled to the injection flange 306. The controller 112 is operably connected to the one or more upper flow controllers 412 to provide a second gas flow 120 comprising a co-flow of the precursor gas and the carrier gas to the upper chamber 338, with the second gas flow 120 having a second precursor mass fraction. The upper flow controllers 412 can regulate the second gas flow 120 to the upper chamber. By controlling the co-flow of precursor and carrier gases, these upper flow controllers 412 can maintain the desired precursor mass fraction in the upper chamber 338.

In some embodiments, the lower precursor conduit 118 is configured to fluidly couple the precursor source assembly 202 to the lower chamber 340 of the chamber body 106. A tee fitting 414a can be configured to fluidly couple the carrier source 222 to the lower precursor conduit 118 for intermixing a carrier gas with a precursor gas flowing through the lower precursor conduit 118. In certain examples, a precursor mass flow controller (MFC) (e.g., lower flow controllers 410) can be configured to control a mass fraction of precursor intermixed with the carrier gas provided to the lower chamber 340 of the chamber body. In other examples, the lower flow controllers 410 can be omitted and a carrier mass flow controller (MFC) (e.g., lower carrier gas MFC 416) can be configured to control a mass fraction of carrier gas intermixed with the precursor provided to the lower chamber 340 of the chamber body. In additional examples, the semiconductor processing system 400 can include both the lower flow controller 410 for controlling the mass fraction of the precursor provided to tee fitting 414a, and the lower flow controllers 410 for controlling the mass fraction of the carrier gas provided to the tee fitting 414a, where the two gas flows intermix in the lower precursor conduit fluidly coupled to the lower chamber 340 of the chamber body. In such examples, the controller 112 can be configured to control a ratio of a mass fraction of precursor of the first gas flow 116 introduced into the lower chamber and therethrough to a substrate supported on the susceptor 328 (via aperture 336).

In some embodiments, the upper precursor conduit 114 is configured to fluidly couple the precursor source assembly 202 to the upper chamber 338 of the chamber body 106. A tee fitting 414b can be configured to fluidly couple the carrier source 222 to the upper precursor conduit 114 for intermixing a carrier gas with a precursor gas flowing through the upper precursor conduit 114. In certain examples, a precursor mass flow controller (MFC) (e.g., upper flow controllers 412) can be configured to control a mass fraction of precursor intermixed with the carrier gas provided to the upper chamber 338 of the chamber body. In other examples, the upper flow controllers 412 can be omitted and a carrier mass flow controller (MFC) (e.g., upper carrier gas MFC 418) can be configured to control a mass fraction of carrier gas intermixed with the precursor provided to the upper chamber 338 of the chamber body. In additional examples, the semiconductor processing system 400 can include both the upper flow controllers 412 for controlling the mass fraction of the precursor provided to tee fitting 414b, and the upper carrier gas MFC 418 for controlling the mass fraction of the carrier gas provided to the tee fitting 414b, where the two gas flows intermix in the upper precursor conduit 114 fluidly coupled to the upper chamber 338 of the chamber body. In such examples, the controller 112 can be configured to control a ratio of a mass fraction of precursor of the second gas flow 120 introduced into the upper chamber 338 and therethrough to the substrate supported on the susceptor 328.

In some embodiments, the first precursor mass fraction is different from the second precursor mass fraction. In such embodiments, the distinction between the precursor mass fractions in the lower and upper chambers allows for tailored processing conditions, accommodating the specific needs of different semiconductor processing steps. By adjusting the precursor mass fractions, the system can optimize the environment for various reactions and material depositions, enhancing the overall efficiency and effectiveness of the semiconductor processing system. For example, the precursor source assembly 202 of semiconductor processing system 400 can comprise one or more dopant sources 216 (as illustrated in FIG. 2) and the first precursor mass fraction of the first gas flow 116 (e.g., a first dopant mass fraction) and the second precursor mass fraction of the second gas flow 120 (e.g., a second dopant mass fraction) can be independently controlled to deposit a doped material layer on a substrate supported on the substrate support (e.g., susceptor 328).

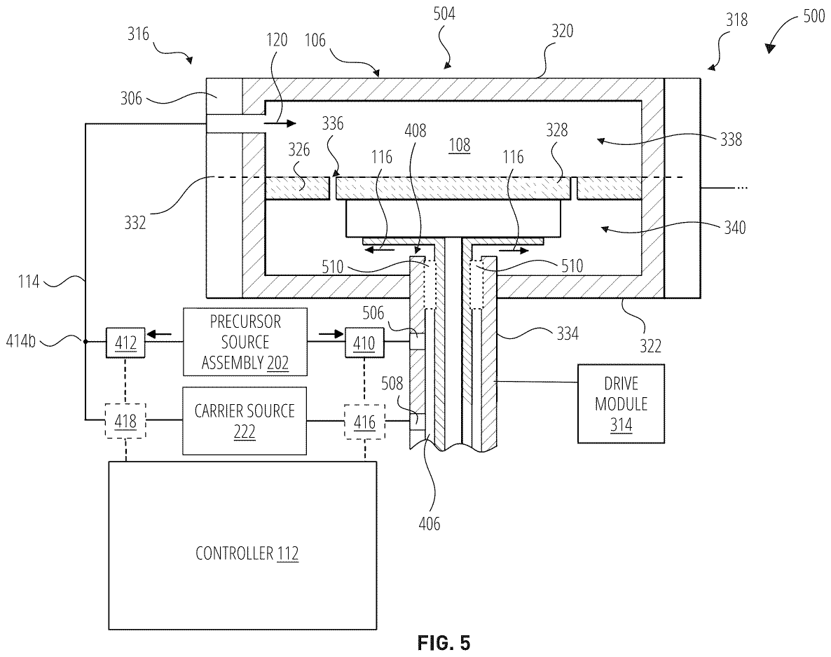

FIG. 5 illustrates a semiconductor processing system 500 including a chamber arrangement 504 in accordance with one or more embodiments of the disclosure. As illustrated in FIG. 5, the tube member 406, configured for introducing the first gas flow 116 into the lower chamber 340, comprises a precursor inlet port 506 and a carrier inlet port 508. In certain examples, both the precursor inlet port 506 and the carrier inlet port 508 can be fluidly coupled to the lower precursor conduit 118. In certain examples, both the precursor inlet port 506 and the carrier inlet port 508 can be fluidly coupled to the tube member 406.

In various embodiments, the precursor inlet port 506 is in fluid communication with the precursor source assembly 202. In certain examples, a precursor mass flow controller (MFC) (e.g., lower flow controllers 410) can be configured to control a mass fraction of precursor introduced into the tube member 406 via precursor inlet port 506. In certain examples, a carrier mass flow controller (e.g., lower carrier gas MFC 416) can optionally be configured to control a mass fraction of carrier gas introduced into the tube member 406 via carrier inlet port 508. In certain examples, the semiconductor processing system 500 can include the lower flow controllers 410 and the lower carrier gas MFC 416. In certain examples, the semiconductor processing system 500 can include the lower flow controllers 410 or the lower carrier gas MFC 416. The controller 112 can be operably connected to at least one of the lower flow controllers 410 and the lower carrier gas MFC 416 to provide the first gas flow 116 comprising a co-flow of the precursor gas and the carrier gas to the lower chamber 340 via the tube member 406, with the first gas flow 116 having a first precursor mass fraction.

In some embodiments, the upper precursor conduit 114 is configured to fluidly couple the precursor source assembly 202 to the upper chamber 338 of the chamber body 106. A tee fitting 414b can be configured to fluidly couple the carrier source 222 to the upper precursor conduit 114 for intermixing a carrier gas with a precursor gas flowing through the upper precursor conduit 114. In certain examples, a precursor mass flow controller (MFC) (e.g., upper flow controllers 412) can be configured to control a mass fraction of precursor intermixed with the carrier gas provided to the upper chamber 338 of the chamber body. In other examples, the upper flow controllers 412 can be omitted and a carrier mass flow controller (MFC) (e.g., upper carrier gas MFC 418) can be configured to control a mass fraction of carrier gas intermixed with the precursor provided to the upper chamber 338 of the chamber body. In additional examples, the semiconductor processing system 500 can include both the upper flow controllers 412 for controlling the mass fraction of the precursor provided to tee fitting 414b, and the upper carrier gas MFC 418 for controlling the mass fraction of the carrier gas provided to the tee fitting 414b, where the two gas flows intermix in the upper precursor conduit 114 fluidly coupled to the upper chamber 338 of the chamber body. In such examples, the controller 112 can be configured to control a ratio of a mass fraction of precursor of the second gas flow 120 introduced into the upper chamber 338 and therethrough to the substrate supported on the susceptor 328.

In various embodiments, the tube member 406 comprises a first precursor outlet 408. The first precursor outlet 408 can be constructed and arranged to direct the first gas flow 116 toward the susceptor 328. In such embodiments, the first precursor outlet 408 can be positioned proximate to the divider 326. In certain examples, the divider 326 includes the aperture 336 and the first precursor outlet 408 can be positioned proximate to the aperture 336 thereby positioning the injection point of the first gas flow proximate to the fluid channel (e.g., the aperture 336) between the lower chamber 340 and upper chamber 338. The first precursor outlet 408 can be positioned downstream of both the carrier inlet port 508 and the precursor inlet port 506. In addition, the precursor inlet port 506 can be disposed downstream of the carrier inlet port 508.

As previously described, the lower precursor conduit 118 can be disposed within a shaft member 334, the shaft member 334 extending through the lower wall 322 of the chamber body 106. The shaft member 334 couples the substrate support 124 to a drive module 314 configured to rotate the substrate support 124. In various embodiments, the tube member 406 is disposed in the shaft member 334 and comprises a portion of the lower precursor conduit 118. In addition, the lower precursor conduit 118 can further include a gas mixing plenum. The gas mixing plenum 510 (as illustrated in FIG. 5) can be positioned downstream of both the precursor inlet port 506 and the carrier inlet port 508 and upstream of the first precursor outlet 408. In addition, the gas mixing plenum 510 can be disposed within the shaft member 334. In certain examples, the gas mixing plenum 510 is in fluid communication with both the precursor source assembly 202 (via precursor inlet port 506) and the carrier source 222 (via carrier inlet port 508) and is configured for mixing (e.g., additional mixing) of the precursor gas and the carrier gas to produce the first gas flow 116 having the first precursor mass fraction.

As with the previous exemplary systems, the controller 112 (of FIG. 5) can be configured to control a ratio of a mass fraction of precursor of the first gas flow 116 introduced into the lower chamber 340 and therethrough to the substrate supported on the susceptor 328 relative to a mass fraction of the second gas flow 120 introduced into the upper chamber 338.

The various embodiments of the disclosure provide methods for depositing a material layer on a substrate employing the semiconductor processing systems described above. The various disclosed methods can employ the introduction of first and second gas flows with different precursor mass fractions in a chamber body, which facilitates enhanced control over the profile of the deposited material layer, and particularly the dopant profile across the substrate. By independently managing the precursor mass fractions in the upper and lower chambers, the methods performed in the semiconductor processing systems of the present disclosure allow for precise modulation of the deposition characteristics at different substrate regions. For example, this dual-flow approach enables targeted adjustments to the dopant concentration, particularly at the substrate edges, where uniformity is often challenging to achieve. The ability to control the precursor mass fraction from both the upper chamber and the lower chamber enables the dopant profile across the whole extent of the deposited material layer to be finely tuned, resulting in improved uniformity and consistency in the electrical properties of the deposited layers. Such methods as performed in the semiconductor processing systems provided can be particularly beneficial in high-pressure and low carrier flow processes, where traditional systems struggle to maintain consistent dopant distribution due to premature mixing of gases. By optimizing the precursor mass fractions independently, the methods disclosed provide robust solutions for achieving desired dopant profiles, thereby enhancing the overall performance and reliability of semiconductor devices.

Turning now to FIG. 6, which illustrates a method 600 for depositing a material layer on a substrate. In various embodiments, method 600 includes the steps of setting up a semiconductor processing system (step 602), introducing a first gas flow having a first precursor mass fraction into a lower chamber (step 604), introducing a second gas flow having a second precursor mass fraction into an upper chamber (step 606), independently controlling the injection of the first and second gas flows (step 608), and depositing the material layer on a substrate (step 610).

In various embodiments, step 602 can include setting up a semiconductor processing system that comprises a gas delivery module. In some embodiments, the gas delivery module comprises at least a precursor source assembly and a carrier source. Accordingly, step 602 can further comprise connecting a chamber body to the gas delivery module and fixing a divider with an aperture within the interior of the chamber body such that the divider separates the interior into an upper chamber and a lower chamber, with the aperture fluidly coupling the two chambers. Further, a susceptor is arranged within the aperture and supported within the interior of the chamber body for rotation about a rotation axis, and a controller is operably connected to the gas delivery module to manage the process.

In accordance with examples of the disclosure, step 604 comprises introducing a first gas flow having a first precursor mass fraction into the lower chamber through a lower precursor conduit. In some embodiments, step 604 is performed such that the deposition characteristics at the lower chamber level, particularly at the substrate's edge, are precisely controlled. In some embodiments, the first gas flow comprises a dopant gas and a carrier gas. In some embodiments, the first gas flow consists essentially of, or consists of, a dopant gas and a carrier gas. In some embodiments, the first gas flow consists essentially of, or consists of, a single dopant gas and a carrier gas. In certain embodiments, the first gas flow comprises a dopant gas selected from the group consisting of a phosphorus dopant gas, an arsenic dopant gas, an antimony dopant gas, a boron dopant gas, an aluminum dopant gas, and a gallium dopant gas. In some embodiments, the first gas flow is free of a material precursor, such as, for example, a silicon-containing precursor, a germanium-containing precursor, and the like. In some embodiments, introducing the first gas flow to the lower chamber further comprises flowing a dopant gas into the lower chamber while flowing a dopant gas through the upper chamber. In some embodiments, introducing the first gas flow to the lower chamber further comprises flowing a silicon-containing precursor, or a germanium-containing precursor, into the upper chamber while flowing the dopant gas through the lower chamber.

In accordance with examples of the disclosure, step 606 comprises introducing a second gas flow 120 having a second precursor mass fraction into the upper chamber 338 through an upper precursor conduit 114. In certain examples, the second precursor mass fraction is different from the first precursor mass fraction, thereby permitting distinct control over the deposition characteristics in the upper chamber 338. In some embodiments, the second gas flow comprises a material precursor gas (e.g., silicon and/or germanium-containing gases), a dopant gas, and a carrier gas. In certain examples, the second gas flow may comprise an etchant gas and a carrier gas, either with or without a material precursor gas. In some embodiments, the second gas flow consists essentially of, or consists of, a material precursor gas, a dopant gas, and a carrier gas. In some embodiments, the second gas flow consists essentially of, or consists of, one or more material precursor gases, a dopant gas, and a carrier gas. In certain embodiments, the second gas flow comprises a dopant gas selected from the group consisting of a phosphorus dopant gas, an arsenic dopant gas, an antimony dopant gas, a boron dopant gas, an aluminum dopant gas, and a gallium dopant gas. In some embodiments, the second gas flow comprises the same dopant gas present in the first gas flow, i.e., the first gas flow and the second gas flow both comprise one of a phosphorus dopant gas, an arsenic dopant gas, an antimony dopant gas, a boron dopant gas, an aluminum dopant gas, and a gallium dopant gas.

In various embodiments, step 608 comprises independently controlling the injection of the first gas flow and the second gas flow into the chamber body. In such embodiments, the independent control of the gas flows (and their precursor mass fractions) facilitates precise adjustments to the deposition process, thereby ensuring that the desired material layer profile is achieved. In some embodiments, independently controlling the injection of the first gas flow further comprises employing one or more lower flow controllers coupled to at least one of the precursor source and the carrier source, and introducing the first gas flow into the lower chamber through a first precursor outlet, the first precursor outlet being in fluid communication with a tube member disposed within a shaft member. In some embodiments, independently controlling the injection of the second gas flow further comprises employing one or more upper flow controllers coupled to at least one of the precursor source and the carrier source, and introducing the second gas flow into the upper chamber through a second precursor outlet, the second precursor outlet comprising an injection flange coupled to an injection end of the chamber body.

In some embodiments, the step of introducing a first gas flow having a first precursor mass fraction into the lower chamber through a lower precursor conduit (step 604), and the step of introducing a second gas flow having a second precursor mass fraction into the upper chamber through an upper precursor conduit (step 606) can be performed simultaneously, or concurrently, or with at least a common time period in which both the first gas flow and the second gas flow are introduced into the chamber body.

In various embodiments, step 610 comprises depositing a material layer on the substrate supported by the substrate support, e.g., a susceptor. In some embodiments, step 610 yields a material layer 128 with a controlled profile in terms of one or more of thickness, composition, and/or doping, thereby meeting specific process requirements. In one example, the precursor source assembly comprises a dopant source and the first precursor mass fraction and the second precursor mass fraction are independently controlled to deposit a doped material layer on the substrate supported on the substrate support, the doped material layer having a dopant percentage non-uniformity of less than 2%, 1%, 0.9%, 0.8%, 0.7%, 0.5%, or between 2% and 0.5 %. In such an example, the material precursor gas can comprise at least one of a silicon-containing precursor and a germanium-containing precursor, and a dopant gas consisting of a phosphorus dopant gas, wherein the dopant percentage non-uniformity is less than 2%, 1%, 0.9%, 0.8%, 0.7%, 0.5%, or between 2% and 0.5%.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing system, comprising:
a chamber body;
a divider with an aperture fixed within an interior of the chamber body, the divider separating the interior of the chamber body into an upper chamber and a lower chamber, the aperture fluidly coupling the lower chamber to the upper chamber;
a substrate support arranged within the aperture and supported within the interior of the chamber body for rotation about a rotation axis;
a gas delivery module connected to the chamber body, the gas delivery module comprising:
a precursor source assembly configured for supplying a precursor gas;
a carrier source configured for supplying a carrier gas;
a lower precursor conduit configured to couple the precursor source assembly and the carrier source to the lower chamber of the chamber body and therethrough the aperture to the upper chamber of the chamber body;
an upper precursor conduit configured to couple the precursor source assembly and the carrier source to the upper chamber of the chamber body; and
a controller operably connected to the gas delivery module and having a non-transitory machine-readable memory with instructions recorded on the memory that cause the controller to independently control a first gas flow through the lower precursor conduit to the lower chamber and a second gas flow through the upper precursor conduit to the upper chamber.

2. The semiconductor processing system of claim 1, wherein the lower precursor conduit comprises a tube member fluidly coupled to the interior of the chamber body.

3. The semiconductor processing system of claim 2, wherein the tube member is disposed within a shaft member, the shaft member extending through a lower wall of the chamber body and couples the substrate support to a drive module configured to rotate the substrate support.

4. The semiconductor processing system of claim 3, further comprising one or more lower flow controllers coupled to the tube member, wherein the controller is operably connected to the one or more lower flow controllers to provide the first gas flow to the lower chamber, the first gas flow having a first precursor mass fraction.

5. The semiconductor processing system of claim 4, wherein the upper precursor conduit comprises an injection flange fluidly coupled to the interior of the chamber body and connected to the chamber body.

6. The semiconductor processing system of claim 5, further comprising one or more upper flow controllers coupled to the injection flange, wherein the controller is operably connected to the one or more upper flow controllers to provide the second gas flow to the upper chamber, the second gas flow having a second precursor mass fraction.

7. The semiconductor processing system of claim 6, wherein the precursor source assembly comprises a dopant source and the first precursor mass fraction and the second precursor mass fraction are independently controlled to deposit a doped material layer on a substrate supported on the substrate support.

8. The semiconductor processing system of claim 3, wherein the tube member further comprises a precursor inlet port fluidly coupled to the precursor source assembly and a carrier inlet port fluidly coupled to the carrier source.

9. A chemical vapor deposition system configured for performing epitaxial deposition processes, comprising:
a reaction chamber comprising a chamber body having an upper wall and a lower wall, wherein the upper wall extends longitudinally between an injection end and a longitudinally opposite exhaust end, wherein the lower wall is below and parallel relative to the upper wall;
a substrate support configured to support a substrate arranged within an interior of the chamber body, the substrate support at least partially defining a lateral plane within the interior;
a gas delivery module connected to the chamber body, the gas delivery module comprising:
a precursor source assembly configured for supplying a precursor gas;
a carrier source configured for supplying a carrier gas;
a lower precursor conduit fluidly coupled to the precursor source assembly and the carrier source by one or more lower flow controllers, the lower precursor conduit being configured to inject a first gas flow into the interior of the chamber below the lateral plane;
an upper precursor conduit fluidly coupled to the precursor source assembly and the carrier source by one or more upper flow controllers, the upper precursor conduit being configured to inject a second gas flow into the interior of the chamber body above the lateral plane; and
a controller operably connected to the gas delivery module and the one or more lower flow controllers and the one or more upper flow controllers and having a non-transitory machine-readable memory with instructions recorded on the memory that cause the controller to independently control a first precursor mass fraction of the first gas flow and a second precursor mass fraction of the second gas flow.

10. The chemical vapor deposition system of claim 9, wherein the upper precursor conduit is coupled to the interior of the chamber body through the injection end of the chamber body.

11. The chemical vapor deposition system of claim 10, wherein the lower precursor conduit is fluidly coupled to a single precursor source and the carrier source.

12. The chemical vapor deposition system of claim 11, wherein the single precursor source comprises a dopant source.

13. The chemical vapor deposition system of claim 12, wherein the lower precursor conduit comprises a first precursor outlet configured to direct the first gas flow toward the substrate support.

14. The chemical vapor deposition system of claim 13, further comprising a divider with an aperture fixed within the interior of the chamber body, the divider separating the interior of the chamber body into an upper chamber and a lower chamber, the aperture fluidly coupling the lower chamber to the upper chamber, wherein the first precursor outlet is positioned proximate to the divider.

15. The chemical vapor deposition system of claim 14, wherein the first precursor outlet is positioned proximate to the aperture of the divider.

16. The chemical vapor deposition system of claim 15, wherein the lower precursor conduit is disposed within a shaft member, the shaft member extending through the lower wall of the chamber body and couples the substrate support to a drive module configured to rotate the substrate support, and wherein the shaft member further comprises a precursor inlet port coupled to the lower precursor conduit and a carrier inlet port coupled to the lower precursor conduit.

17. The chemical vapor deposition system of claim 16, wherein the lower precursor conduit further comprises a gas mixing plenum disposed within the shaft member, the gas mixing plenum is positioned downstream of both the precursor inlet port and the carrier inlet port and upstream of the first precursor outlet, the gas mixing plenum being in fluid communication with both the precursor source assembly via the precursor inlet port and the carrier source via the carrier inlet port, wherein the gas mixing plenum is configured for mixing the precursor gas and the carrier gas to produce the first gas flow having the first precursor mass fraction.

18. A method for depositing a material layer on a substrate, the method comprising:
at a semiconductor processing system including a gas delivery module comprising at least a precursor source assembly and a carrier source; a chamber body connected to the gas delivery module; a divider with an aperture fixed within an interior of the chamber body, the divider separating the interior of the chamber body into an upper chamber and a lower chamber, the aperture fluidly coupling the lower chamber to the upper chamber; a substrate support arranged within the aperture and supported within the interior of the chamber body for rotation about a rotation axis; and a controller operably connected to the gas delivery module,
introducing a first gas flow having a first precursor mass fraction into the lower chamber through a lower precursor conduit;
introducing a second gas flow having a second precursor mass fraction into the upper chamber through an upper precursor conduit, the second precursor mass fraction being different from the first precursor mass fraction;
independently controlling the injection of the first gas flow and the second gas flow into the chamber body; and
depositing the material layer on the substrate supported by the substrate support.

19. The method of claim 18, wherein independently controlling the injection of the first gas flow further comprises, employing one or more lower flow controllers coupled to at least one of the precursor source assembly and the carrier source, and introducing the first gas flow into the lower chamber through a first precursor outlet, the first precursor outlet being in fluid communication with a tube member disposed within a shaft member.

20. The method of claim 19, wherein independently controlling the injection of the second gas flow further comprises, employing one or more upper flow controllers coupled to at least one of the precursor source assembly and the carrier source, and introducing the second gas flow into the upper chamber through a second precursor outlet, the second precursor outlet comprising an injection flange coupled to an injection end of the chamber body.
